(19) United States
(12) Patent Application Publication
(10) Pub. No.: US 2024/0396501 A1
(43) Pub. Date: Nov. 28, 2024

(54) DISTRIBUTED POWER AMPLIFIER

(71) Applicant: NEC Corporation, Tokyo (JP)

(72) Inventor: Keiichi MOTOI, Tokyo (JP)

(73) Assignee: NEC Corporation, Tokyo (JP)

(21) Appl. No.: 18/641,537

(22) Filed: Apr. 22, 2024

(30) Foreign Application Priority Data
May 22, 2023 (JP) 2023-083656

(51) Int. Cl. H03F 1/18; H03F 3/24

(52) U.S. Cl. CPC H03F 1/18; H03F 3/245; H03F 2200/451

(57) ABSTRACT

A distributed power amplifier includes a two-divider that divides an input signal into two signals, a main amplifier that amplifies one of the two signals, (N-1) dividers that divide another of the two signals into (N-1) signals, (N-1) auxiliary amplifiers that amplify (N-1) signals, and (N-1) stages of transmission lines connected in series with one another. An output end of the main amplifier is connected to an end portion on an input side of a first-stage transmission line. Output ends of the (N-1) auxiliary amplifiers are connected to end portions on an output side of the (N-1) stages of transmission lines, respectively. The (N-1) auxiliary amplifiers include an auxiliary amplifier having a maximum output voltage that is larger than maximum output power of the main amplifier.

### INCORPORATION BY REFERENCE

This application is based upon and claims the benefit of priority from Japanese patent application No. 2023-083656, filed on May 22, 2023, the disclosure of which is incorporated herein in its entirety by reference.

### TECHNICAL FIELD

The present disclosure relates to a distributed power amplifier.

### BACKGROUND ART

Recently, upgrading of wireless communication represented by fifth generation mobile communication system (5G) has been advanced. In order to improve high functionality (e.g., beamforming) and a communication speed of a wireless apparatus, use of a high frequency band such as a sub-6 GHz band and a millimeter wave band in which a frequency band is more easily secured is advanced.

Meanwhile, due to high straightness of the high-frequency band, a large number of radio units (RU) need to be installed. In order to secure an installation place, it is required to improve installation property of the radio unit. Therefore, miniaturization of the radio unit is required. However, a power amplifier (PA) occupies a large proportion of power consumption of the radio unit, leading to an increase in size of a mechanism such as a heat dissipation fin. High efficiency of power conversion efficiency (hereinafter referred to as efficiency) is an important technical problem for achieving miniaturization of the radio unit. In addition, reduction of environmental load for achieving carbon neutral is strongly demanded, and from this viewpoint, high efficiency which leads to low power consumption is an important technical problem. An orthogonal frequency division multiplexing (OFDM) signal to be used in radio communications has a higher peak to average power ratio (PAPR). Since such a signal has a large ratio of low-power signals, high efficiency during a back-off operation is required. In addition, with demand for broadband use of a frequency in a high frequency band such as a sub-6 GHz band and a millimeter wave band in which a frequency band is more easily secured, broadband is also required.

For example, Japanese Unexamined Patent Application Publication No. 2010-118824 (hereinafter, Patent Literature 1) discloses a multi-stage Doherty PA as a method for achieving high back-off efficiency. At an input power level (also referred to as an input level) before and after a main amplifier starts a saturation operation, an auxiliary amplifier performs operation in stages depending on the input level.

Xuan Anh Nghiem, Junqing Guan and Renato Negra, “Design of a Broadband Three-Way Sequential Doherty Power Amplifier for Modern Wireless Communications”, IEEE MTT-S Int. Microw. Symp. Dig., 2014, pp. 1-3. (hereinafter, Non Patent Literature 1) discloses a method for achieving high efficiency in broadband. In a three-stage Doherty power amplifier having a plurality of auxiliary amplifiers, an impedance line having a λ/4 length connects an output of a main amplifier section and an output of a first auxiliary amplifier. λ represents a wavelength corresponding to a center frequency of a predetermined frequency band. The first auxiliary amplifier starts operation at a power level before and after the output of the main amplifier is saturated. A characteristic impedance value of the impedance line is set to a suitable value by adjusting an output power back-off value and drain bias voltages. An output impedance, which is load-modulated by saturation operation of a second auxiliary amplifier, is set to reach about 50Ω, which is generally applied. An impedance conversion circuit that limits frequency characteristics is not required, and the three-stage Doherty PA achieves broadband operation.

Paul Saad et. al., “A 1.8-3.8-GHz Power Amplifier With 40% Efficiency at 8-dB Power Back-Off”, IEEE Transactions on Microwave Theory and Techniques, vol. 66, no. 11, pp. 4870-4882, September 2018. (hereinafter, Non Patent Literature 2) discloses a distributed high-efficiency PA (Distributed Efficient PA). The distributed high-efficiency PA includes a main amplifier, auxiliary amplifiers of (N-1) stages (N is a natural number of 3 or more), and a broadband impedance conversion circuit of (N-1) stages. The main amplifier operates alone when an output power level is low. The auxiliary amplifier starts operation at once from an input level before and after an output of the main amplifier is saturated. By appropriately setting an output level of each amplifier in the distributed high-efficiency PA disclosed in Non Patent Literature 2, it is possible to suppress load modulation of the main amplifier occurring in the Doherty PAs described in Patent Literature 1 and Non Patent Literature 1. The load modulation represents variations in loads of the main amplifier and the auxiliary amplifier between during low output and during high output. The distributed high-efficiency PA can achieve broadband optimum impedance matching of the main amplifier with respect to efficiency, output power, and the like over the entire range of operating power.
Patent Literature 1: Japanese Unexamined Patent Application Publication No. 2010-118824
Non-patent Literature 1: Xuan Anh Nghiem, Junqing Guan and Renato Negra, “Design of a Broadband Three-Way Sequential Doherty Power Amplifier for Modern Wireless Communications”, IEEE MTT-S Int. Microw. Symp. Dig., 2014, pp. 1-3.
Non-patent Literature 2: Paul Saad et. al., “A 1.8-3.8-GHz Power Amplifier With 40% Efficiency at 8-dB Power Back-Off”, IEEE Transactions on Microwave Theory and Techniques, vol. 66, no. 11, pp. 4870-4882 September 2018.

### SUMMARY

In the Doherty PA disclosed in Patent Literature 1, the main amplifier and an auxiliary amplifier group are connected by a single λ/4 length transmission line. Therefore, a frequency characteristic of a combining circuit becomes narrow-band, it is difficult to cope with broadband.

The three-stage Doherty PA disclosed in Non Patent Literature 1 does not require an impedance conversion circuit that limits the frequency characteristic. The impedance conversion circuit is a circuit that connects the auxiliary amplifier of the second stage and an output load in the related art. However, load modulation occurs between during the low output operation and during the high output operation of the main amplifier, it is necessary to consider impedance matching to a load during the both operations in an operating frequency band. Therefore, a frequency band that maintains good characteristics is limited.

In the distributed efficiency PA disclosed in Non Patent Literature 2, a size of each amplifier element (amplifying element) is the same. The amplifying element such as a field effect transistor (FET) increases in size and increases in parasitic capacitance. Therefore, a frequency band that can be matched is limited. Therefore, in particular when configuring a high output PA, a frequency characteristic capable of maintaining high efficiency becomes narrow-band, and a broadband characteristic is impaired. Specifically, the optimum impedance of the main amplifier is lowered, a conversion ratio with a desired impedance that is constant over the operating power level is increased, and it is difficult to achieve high-efficiency matching in broadband. Then, it becomes difficult to achieve high back-off efficiency in broadband. Further, a desired impedance value for each auxiliary amplifier after the operation of the auxiliary amplifier group and a variation range thereof are large. In particular, a conversion ratio between a desired impedance value and low optimum impedance is large, and it is difficult to achieve optimum high-efficiency matching in broadband.

The present disclosure has been made in order to solve such problems, and an example object thereof is to provide a distributed power amplifier that operates with high efficiency in a wide frequency band.

In a first example aspect of the present disclosure, a distributed power amplifier includes: a two-divider configured to divide an input signal into two signals; a main amplifier configured to amplify one of the two signals; a (N-1) divider configured to divide another of the two signals into (N-1) (N is a natural number of 3 or more) signals; (N-1) auxiliary amplifiers configured to amplify the (N-1) signals, respectively; and (N-1) stages of transmission lines having different characteristic impedances from one another and being connected in series with one another, wherein an output end of the main amplifier is connected to an end portion on an input side of a transmission line in a first stage of the (N-1) stages of transmission lines, output ends of the (N-1) auxiliary amplifiers are connected to end portions on an output side of the (N-1) stages of transmission lines, respectively, only the main amplifier performs amplification operation when a power level of the input signal is small, and the (N-1) auxiliary amplifiers start operation at once after a power level of an output signal of the main amplifier reaches a predetermined power level, and the (N-1) auxiliary amplifiers include an auxiliary amplifier having maximum output power larger than maximum output power of the main amplifier.

### BRIEF DESCRIPTION OF DRAWINGS

The above and other aspects, features, and advantages of the present disclosure will become more apparent from the following description of certain example embodiments when taken in conjunction with the accompanying drawings, in which:

FIG. 1 is a configuration diagram of a distributed power amplifier according to a first example embodiment;

FIG. 2 is a configuration diagram of the distributed power amplifier according to the first example embodiment;

FIG. 3A is a configuration diagram of a simple equivalent circuit when parasitic capacitance during a low-output operation of the distributed power amplifier according to the first example embodiment is ignored;

FIG. 3B is a configuration diagram of an equivalent circuit when the parasitic capacitance during the low-output operation of the distributed power amplifier according to the first example embodiment is taken into consideration;

FIG. 3C is a configuration diagram of an equivalent circuit when parasitic capacitance during a high-output operation of the distributed power amplifier according to the first example embodiment is taken into consideration;

FIG. 4 is a Smith chart illustrating a simulation result of the optimum load impedance of a power amplifying element constituting the distributed power amplifier according to the first example embodiment;

FIG. 5 is a diagram illustrating load modulation characteristics of a main amplifier and an auxiliary amplifier constituting the distributed power amplifier according to the first example embodiment, and a theoretical analysis value of the real part of the optimum load impedance of each power amplifying element;

FIG. 6 is a diagram illustrating a simulation result of load modulation characteristics of the main amplifier and the auxiliary amplifier constituting the distributed power amplifier according to the first example embodiment;

FIG. 7 is a diagram illustrating a simulation result of drain efficiency characteristics of the distributed power amplifier according to the first example embodiment;

FIG. 8 is a configuration diagram of a distributed power amplifier according to another example embodiment;

FIG. 9 is a configuration diagram of a distributed power amplifier according to another example embodiment;

FIG. 10A is a configuration diagram of a distributed power amplifier according to another example embodiment;

FIG. 10B is a configuration diagram of a distributed power amplifier according to another example embodiment; and

FIG. 11 is a configuration diagram of a distributed power amplifier according to another example embodiment.

### EXAMPLE EMBODIMENT

Hereinafter, example embodiments are explained with reference to the drawings. Note that, since the drawings are simplified, the technical scope of the example embodiments is not ought to be construed narrowly based on the description of the drawings. In addition, the same elements are denoted by the same reference numerals, and redundant explanation thereof is omitted.

In the following example embodiments, when necessary for convenience, explanation is divided into a plurality of sections or example embodiments. However, unless otherwise specified, they are not unrelated to one another, and one of them is related to a part or whole of another, such as a modified example, an application example, a detailed explanation, and a supplementary explanation. In addition, in the following example embodiments, when reference is made to the number and the like (including the number of pieces, a numerical value, an amount, a range, and the like) of elements, the number is not limited to a specific number, and may be a specific number or more or less, unless otherwise specified and considered to be clearly limited to the specific number in principle.

Furthermore, in the following example embodiments, components thereof (including an operation step and the like) are not necessarily essential unless otherwise specified and considered to be essential in principle, and the like. Similarly, in the following example embodiments, when referring to a shape, a positional relationship, and the like of components, or the like, it is intended to include substantially approximate or similar shape and the like to the shape thereof and the like unless otherwise specified and in principle is considered to be clearly not the same. This also applies to the above-mentioned number and the like (including the number of pieces, a numerical value, an amount, a range, and the like).

### History of Study up to Arrival at Power Amplifier According to Example Embodiment

As a method of achieving high back-off efficiency, for example, there is a Doherty amplifier described in Patent Literature 1. Load modulation occurs between during a low-power operation in which only the main amplifier operates alone and during a high-power operation in which an auxiliary amplifier group operates together with the main amplifier from before and after saturation operation of the main amplifier. Therefore, an optimum impedance value for achieving high efficiency for the main amplifier is different between during the low-power operation and during the high-power operation. Therefore, an appropriate impedance value in consideration of both during the low-power operation and during the high-power operation needs to be selected. In addition, since the main amplifier and the auxiliary amplifier group are connected by a single λ/4 length transmission line, the frequency characteristic become narrow-band as a combining circuit, and it is difficult to cope with the widening of the band. This characteristic is also a common problem in general Doherty amplifiers.

To solve these problems, for example, Non Patent Literature 2 discloses a high-efficiency amplifier (hereinafter referred to as a distributed power amplifier) called “distributed type (Distributed)” as a method for achieving high back-off efficiency in broadband. The distributed power amplifier includes one main amplifier, an auxiliary amplifier group, and an N-stage impedance circuit. The one main amplifier operates alone at low power. The auxiliary amplifier group includes (N-1) auxiliary amplifiers (N: three or more natural numbers) that operate in conjunction with the main amplifier from before and after the saturation operation of the main amplifier. The N-stage impedance conversion circuit also serves as a combining circuit for each amplifier output. In the distributed amplifier disclosed in Non Patent Literature 2, the size and output power of each amplifying element are assumed to be the same for both the main amplifier and the auxiliary amplifier group. In short, the same field effect transistor (FET) is used as the main amplifier and the auxiliary amplifier.

In the distributed power amplifier, unlike the general Doherty amplifier described above, load modulation during the low-power operation and the high-output operation of the main amplifier section is suppressed. Therefore, an optimum impedance value for achieving high efficiency for the main amplifier can be maintained at a constant value, and high efficiency can be maintained by common impedance matching in the entire operating power range. In addition, since the impedance is uniquely determined at each operating frequency, highly efficient impedance matching of the main amplifier in broadband is simplified. In addition, various kinds of broadband impedance conversion circuits such as Chebyshev type having ripple characteristics in a band or the like can be applied to the N-stage impedance conversion circuit. This facilitates impedance matching in a desired band.

When the amplifying elements of the amplifiers have the same size (associated to a magnitude of output power) as in the distributed power amplifier according to Non Patent Literature 2, a parasitic capacitance Cₚ also increases as the size of the amplifying element increases. The parasitic capacitance Cₚ includes, for example, a drain-to-source capacitance C_{ds}. For bonding connection, the parasitic capacitance Cₚ may include a parasitic capacitance C_{pad} of a pad portion of a substrate-side bonding area. An increase in the parasitic capacitance Cₚ is particularly pronounced in constituting high-output power amplifier. The optimum impedance of the main amplifier decreases, and a conversion ratio between the desired impedance that is constant over the entire operating power level and the optimum impedance of the main amplifier increases, thereby making it difficult to achieve high-efficiency matching in broadband. Therefore, the frequency band in which high efficiency can be maintained becomes narrower, and the broadband characteristics are impaired.

Also, due to the load modulation in the auxiliary amplifier group, the load monotonically decreases from infinity to a finite value Z_{(A,i)} (i=1 to (N-1)) during a period from the start of the operation until the saturation operation. A relation of Z_{(A,1)}>Z_{(A,2)}> . . . >Z_{(A,(N-1))} is established from Z_{(A,1)} of the first stage to Z_{(A,(N-1))} of the final stage of the auxiliary amplifiers. Therefore, Z_{(A, 1)} of the first stage is required to satisfy a particularly high-impedance condition. Therefore, when the parasitic capacitance Cₚ is large, an output impedance decreases, an impedance conversion ratio with respect to the optimum impedance Z_{(A,1)} increases, the frequency band in which high efficiency can be maintained becomes narrower, and the broadband property is impaired.

Therefore, a distributed power amplifier according to the following example embodiments has been found that can solve such a problem.

### First Example Embodiment

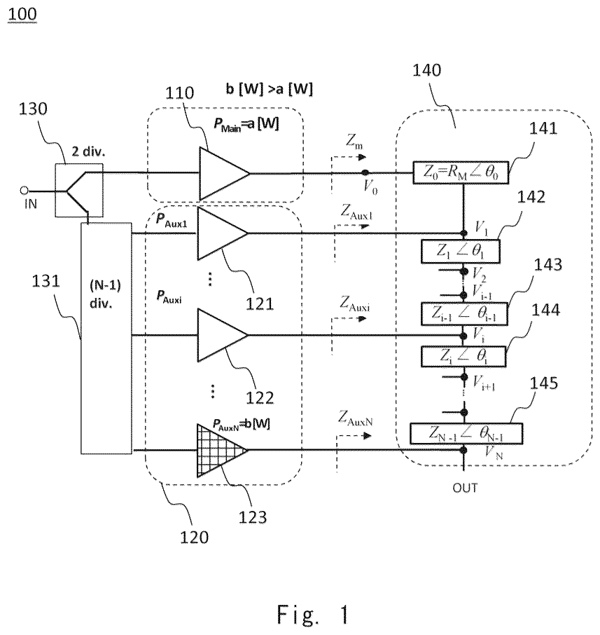

An example of the present disclosure is explained with reference to FIG. 1. A distributed power amplifier 100 of N stages (N is a natural number of 3 or more) according to a first example embodiment includes a main amplifier 110 and an auxiliary amplifier group 120. The auxiliary amplifier group 120 includes auxiliary amplifiers arranged in the (N-1) stage. The main amplifier is arranged above the auxiliary amplifier group 120. In other words, a downward direction represents a direction in which the auxiliary amplifier group 120 is viewed from the main amplifier 110. The main amplifier 110 and the (N-1) stage auxiliary amplifier are connected in parallel to each other. To the main amplifier 110, a bias voltage to be used for a degree of Class AB to B operation is applied. The auxiliary amplifiers included in the auxiliary amplifier group 120 simultaneously start operation at input levels before and after the main amplifier 110 performs saturation operation. To the auxiliary amplifier group 120, a bias voltage of a degree of Class B to C operation is applied. The (N-1) auxiliary amplifiers constituting the auxiliary amplifier group 120 include an auxiliary amplifier 123. The auxiliary amplifier 123 has a larger maximum output power b than a maximum output power a of the main amplifier 110. The auxiliary amplifier 123 is disposed at a stage after the second stage from the top, as an example, at the lowermost stage (also referred to as the final stage). In the distributed power amplifier 100, the maximum output power of the main amplifier is different from the maximum output power of the auxiliary amplifier 123. The distributed power amplifier 100 is an asymmetric distributed power amplifier.

A two-divider 130 divides an input signal into two signals. The main amplifier 110 amplifies one of the two signals. (N-1) dividers 131 divide another of the two signals into (N-1) signals. (N-1) auxiliary amplifiers amplify the (N-1) signals, respectively. When a power level of the input signal is small, only the main amplifier 110 performs an amplification operation, and after the power level of an output signal of the main amplifier reaches a predetermined power level, the (N-1) auxiliary amplifiers are configured to start the operation at once. The auxiliary amplifier group 120 may include an auxiliary amplifier (for example, auxiliary amplifiers 121 to 122) having a maximum output voltage substantially the same as the maximum output power of the main amplifier 110, and an auxiliary amplifier (for example, the auxiliary amplifier 123) having a maximum output voltage larger than the maximum output power of the main amplifier.

At the two-divider 130, one half of the input signal to the distributed power amplifier 100 is distributed to the main amplifier 110. At the two-divider 130 and the (N-1) dividers 131, 1/[2(N-1)] of the input signal to the distributed power amplifier 100 is distributed to each auxiliary amplifier. Note that, although a delay circuit or the like needs to be arranged on an input side of each amplifier, depending on a phase difference on an output side of each amplifier, illustration is omitted. In each figure, a circuit such as a delay circuit is included inside the main amplifier 110 and the auxiliary amplifiers 121 to 123.

A bias voltage of the main amplifier 110 is set in such a way that the main amplifier 110 operates in Class A or Class AB. The bias voltages of the (N-1) auxiliary amplifiers are set in such a way that the (N-1) auxiliary amplifiers operate in Class C.

Output signals from the main amplifier 110 and the (N-1) auxiliary amplifiers of the auxiliary amplifier group 120 may be combined by a combining circuit 140 and output to an impedance conversion circuit, which is not illustrated. The combining circuit 140 includes, by way of example, (N-1) stages of transmission lines each having a λ/4 length, which is connected in series with each other. λ represents a wavelength corresponding to a center frequency of a predetermined frequency band. In short, an electrical length of each transmission line may be approximately 90 degrees. An output end of the main amplifier 110 is connected to an end portion on an input side of a first stage transmission line 141. Output ends of the (N-1) auxiliary amplifiers are connected to end portions on an output side of (N-1) stages of transmission lines, respectively. The end portion on the output side is an end portion on the opposite side to the end portion on the input side. Herein, a characteristic impedance and an electric length of the i-th stage transmission line in transmission lines 141 to 145 each having a λ/4 length included in the combining circuit 140 are expressed as Zᵢ and θᵢ (i=0 to (N-1)), respectively. For determination of the characteristic impedance and the electrical length, processing related to various broadband impedance conversion circuits such as a Chebyshev type having an equal ripple characteristic in the band can be applied. This facilitates impedance matching in a desired band. For example, the characteristic impedance of the (N-1)-stages of transmission lines may be set in such a way that the combining circuit 140 forms a Chebyshev-type broadband impedance conversion circuit. A specific value of Zᵢ depends on the type of the combining circuit 140. As the number of stages increases, analytical derivation becomes complicated, but a numerical solution can be easily acquired by using various electronic design automation (EDA) tools or the like. As an example, for impedance conversion from R_{L} to Z₀=R_{M} in the three-stage Chebyshev type, R_{L}, R_{M} are respectively set as Equations (1) and (2). k represents any maximum reflection coefficient. An output impedance of the distributed power amplifier 100 is represented by R_{L}. An output impedance of the main amplifier is represented by R_{M}. An output back-off point is represented by output back off (OBO)[dB]. Maximum output power is represented by Pₘₐₓ. A drain bias voltage is represented by V_{dd}. A knee voltage, i.e., a drain voltage near the border of the linear-saturation operation, is represented by Vₖ.

$$\begin{matrix}[ Mathematical formula 1 ] & \\ {R}_{L} = \frac{{V}_{α}^{2}}{2 {P}_{max}} = \frac{1}{2 {P}_{max}} {\{ \frac{π ( {V}_{dd} - {V}_{k} )}{2 ( π - 1 )} \}}^{2} & ( 1 )\end{matrix}$$

$$\begin{matrix}[ Mathematical formula 2 ] & \\ {R}_{M} = {R}_{L} \cdot {10}^{\frac{OBO}{10}} & ( 2 )\end{matrix}$$

In this case, Equations (3) and (4) for Z₁ are established (Ref.: Collin, Robert E, “Foundations for Microwave Engineering”, 2nd ed, pp. 359, IEEE, 2001.).

$$\begin{matrix}[ Mathematical formula 3 ] & \\ {k}^{2} = \frac{{( {R}_{L} - {Z}_{0} )}^{2}}{4 {Z}_{L} {Z}_{0}} {( \frac{2 cos {θ}_{z}}{3 \sqrt{3} {tan}^{2} {θ}_{z}} )}^{2} & ( 3 )\end{matrix}$$

$$\begin{matrix}[ Mathematical formula 4 ] & \\ \frac{{R}_{L} - {Z}_{0}}{{tan}^{2} {θ}_{z}} = \frac{{Z}_{1}^{2}}{{Z}_{0}^{2}} + 2 {{Z}_{1} ( \frac{{R}_{L}}{{Z}_{0}} )}^{1 / 2} - \frac{{Z}_{L} {Z}_{0}^{2}}{{Z}_{1}^{2}} - 2 {( \frac{{R}_{L}}{{Z}_{0}} )}^{\frac{1}{2}} \frac{{Z}_{0}^{2}}{{Z}_{1}^{2}} & ( 4 )\end{matrix}$$

Equation (4) is a quadratic equation for Z₁. Z₁ is determined by solving Equation (4) using θ_{z} calculated from Equation (3). Z₂ and Z₃ are calculated by Equations (5) and (6).

$$\begin{matrix}[ Mathematical formula 5 ] & \\ {Z}_{2} = \sqrt{{R}_{M} \cdot {R}_{L}} & ( 5 )\end{matrix}$$

$$\begin{matrix}[ Mathematical formula 6 ] & \\ {Z}_{3} = \frac{{R}_{M} \cdot {R}_{L}}{{Z}_{1}} & ( 6 )\end{matrix}$$

Generally, R_{M}>Z₁>Z₂>Z₃>( . . . >Z_{(N-1)})>R_{L} is established. The combining circuit 140 having other types of transmission characteristics may be used, such as a maximum flat type that is different from the Chebyshev type. Design conditions for high-efficiency matching by harmonic matching are taken into consideration, and a suitable combining circuit 140 may be appropriately selected and used.

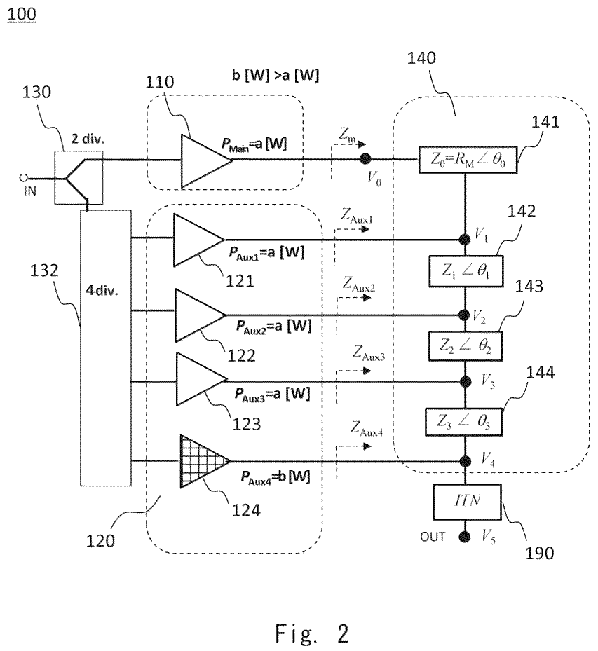

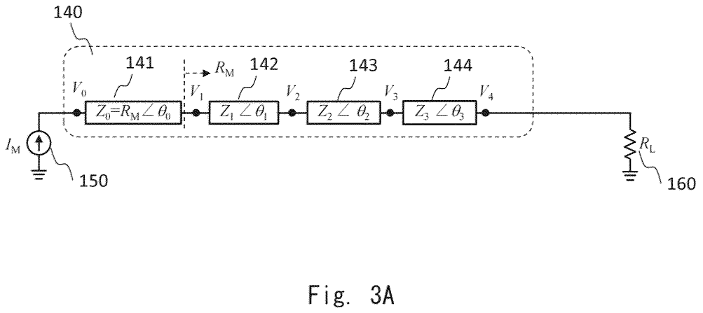

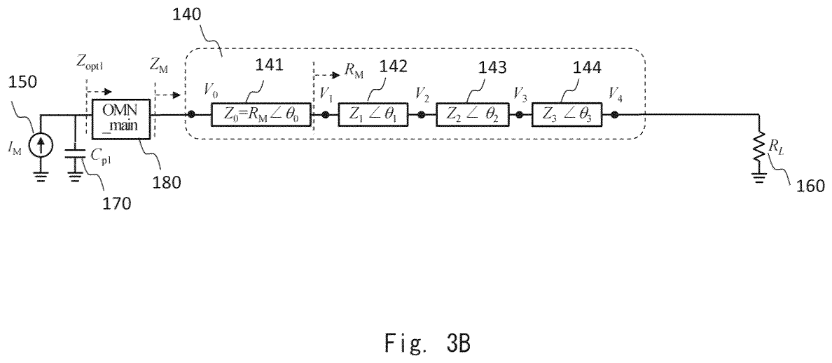

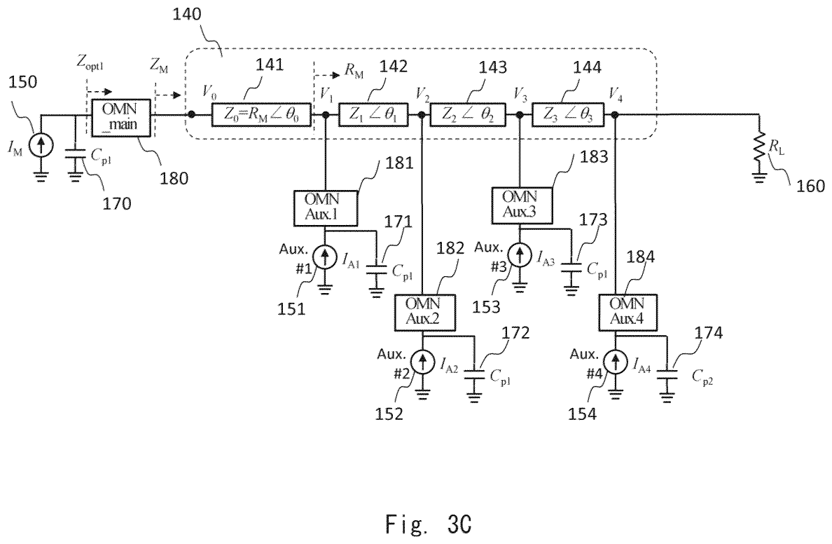

As a configuration example of a specific example embodiment, FIG. 2 illustrates an example of a configuration of the distributed power amplifier 100 in a case where N=4 in FIG. 1 and an auxiliary amplifier 124 having a maximum output power b is arranged at the final stage. An output power distribution of amplifiers in the distributed power amplifier 100 is asymmetric. The distributed power amplifier 100 includes a single-stage main amplifier and four stages of auxiliary amplifiers. Hereinafter, efficacy of the first example embodiment based on the present configuration is illustrated together with results of simulation analysis. FIG. 3A illustrates a simple equivalent circuit diagram at a low power level in which only the main amplifier in the distributed power amplifier 100 operates. A main amplifier current source 150 and the combining circuit 140 (a four-stage configuration of the transmission lines 141 to 144) are connected to a load 160 (R_{L}).

However, as illustrated in FIG. 3B, in an actual amplifying element, the main amplifier current source 150 is accompanied by a parasitic capacitance 170 (Cₚ₁). The parasitic capacitance 170 is, for example, a drain-to-source capacitance Cds of the FET. The parasitic capacitance 170 basically increases with an increase in the maximum output power of the main amplifier 110. An output matching circuit (OMN: Output Matching Network) 180 in a stage preceding to the combining circuit 140 performs impedance matching with respect to a desired impedance Z₀ (for example, Zₘ). The parasitic capacitance 170 lowers the output impedance and lowers an optimum impedance Zₒₚₜ₁ of the main amplifier. Ideally, a desired impedance Z₀ is constant across the entire operating power level. Since a conversion ratio between the output impedance of the main amplifier 110 and the desired impedance Z₀ thereof increases, it is difficult to achieve high-efficiency matching in broadband.

FIG. 3C is a configuration diagram of an equivalent circuit of the distributed power amplifier 100 during high-output operation. As compared with FIG. 3B, the distributed power amplifier 100 further includes auxiliary amplifier current sources 151 to 154, output matching circuits 181 to 184, and parasitic capacitances 171 to 174. The parasitic capacitances 171 to 173 are defined as Cₚ₁, and the parasitic capacitance 174 is defined as Cₚ₂. Cₚ₂ is larger than the Cₚ₁.

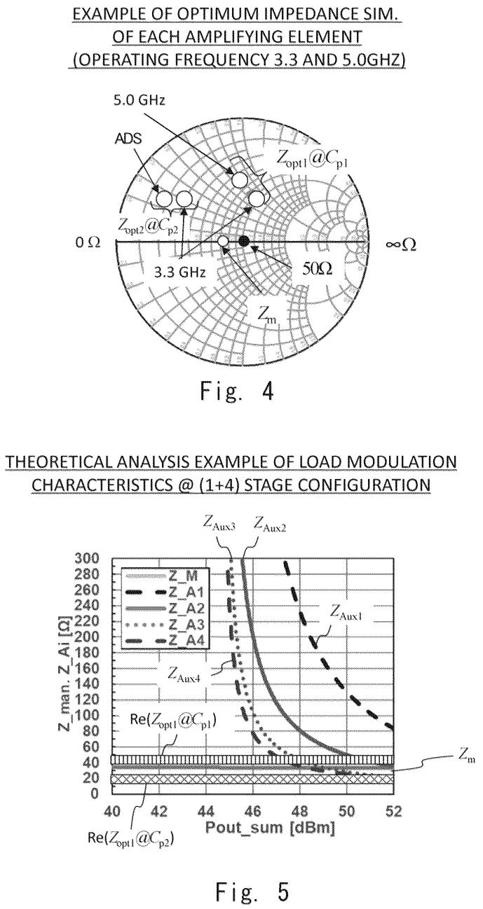

FIG. 4 illustrates results of a specific simulation analysis of the optimum load impedance on a Smith chart. An operating condition of each amplifying element has been set to a degree of Class B operation. The maximum output voltage of each amplifying element, which is an FET element, has been set to about 10 W or about 30 W. A signal frequency has been set to 3.3 GHz or 5.0 GHz. Zₘ, which is an example of the desired impedance in the first example embodiment, is also illustrated together. As described above, in a 30 W-class FET element having a high maximum output power, the optimum load impedance is low. Therefore, in the 30 W-class element, an impedance conversion ratio with respect to Zₘ is large. On the other hand, in a 10 W-class element, the impedance conversion ratio is suppressed to be low. Therefore, in the first example embodiment, an auxiliary amplifier having the maximum output power b is used as the final stage of the auxiliary amplifier group 120, i.e., the auxiliary amplifier 124 in the fourth stage of the auxiliary amplifier group. A low output element having a maximum output power a is used as the main amplifier 110 and the auxiliary amplifiers 121 to 123. With this configuration, the parasitic capacitance 170 is kept lower than the parasitic capacitance 174 (Cₚ₂). Therefore, the impedance conversion ratio is reduced, and high-efficiency matching with respect to the main amplifier 110 is easily achieved in broadband.

FIG. 5 illustrates results of a theoretical analysis of load modulation characteristics in the distributed power amplifier 100 having a five-stage configuration. FIG. 5 illustrates a theoretical analysis value of a real part of an optimum load impedance of each amplifier (also referred to as an amplifying element). A graph illustrates dependency of Zₘ and Z_{Aux1} to Z_{Aux4} on the total output power Pout_sum. Zₘ represents the desired impedance to the main amplifier 110. Z_{Aux1} to Z_{Aux4} represent desired impedances to the auxiliary amplifiers 121 to 124. Pout_sum represents a total output power by the distributed power amplifier 100.

Ideally, Z_{Aux1} to Z_{Aux4} monotonically decreases from infinity to finite values between when the auxiliary amplifiers 121 to 124 start operation and when the operation is saturated. A relation of Z_{Aux1}>Z_{Aux2}>Z_{Aux3}>Z_{Aux4} is established in Z_{Aux(N-1)} of the final stage from Z_{Aux1} of the first stage of the auxiliary amplifier. Therefore, Z_{Aux1} is required to be particularly high impedance. On the other hand, the desired impedance in the subsequent stage becomes a low impedance. Since a high-output amplifier of 30 W class element having a large parasitic capacitance and a low optimum load impedance is arranged in the subsequent stage (e.g., the final stage), the above-described impedance conversion ratio is reduced. For example, high efficiency matching with respect to the auxiliary amplifier 124 at the final stage of the auxiliary amplifier group is easily achieved in broadband.

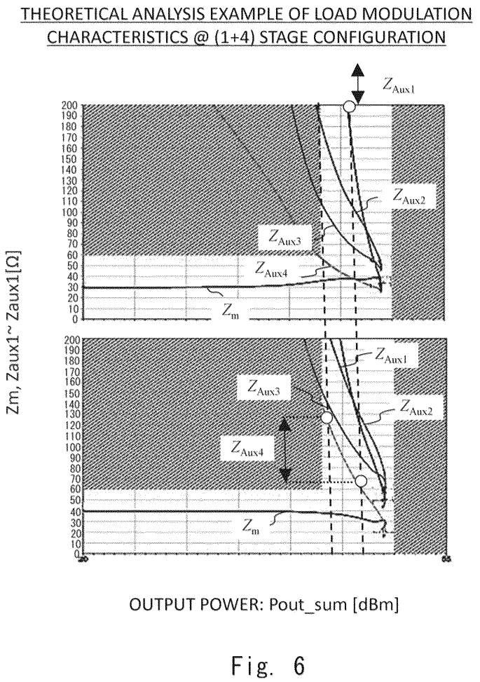

FIG. 6 illustrates simulation results of load modulation characteristics in the distributed power amplifier 100 including the main amplifier 110 and the four stages of auxiliary amplifiers. The above figure illustrates a simulation result when a model of a 30 W class element (e.g., GaN FET) is applied to the auxiliary amplifier 121 of the first stage and a model of a 10 W class element is applied to the other amplifiers. The figure below illustrates a simulation result when a model of a 30 W class element (e.g., GaN FET) is applied to the auxiliary amplifier 124 of the final stage (in the fourth stage) and a model of a 10 W class element is applied to the other amplifiers. It may be considered that a region between two dotted lines extending in the up-down direction is associated to a load modulation region.

Referring to the above figure, the desired impedance Z_{Aux1} of the auxiliary amplifier 121 of the first stage is several hundreds Ω or more. Therefore, when the 30 W class element is arranged in the first stage, the impedance conversion ratio is high, high efficiency matching becomes difficult, and efficiency is lowered. Double-sided arrows indicate an amount of variation in the desired impedance Z_{Aux1}.

Referring to the figure below, the desired impedance Z_{Aux4} of the auxiliary amplifier 124 of the final stage is much lower than the desired impedance Z_{Aux1} described above. Therefore, when the 30 W class element having a small optimum load impedance is arranged in the final stage, high-efficiency matching is easy and efficiency is improved. Double-sided arrows indicate an amount of variation in the desired impedance Z_{Aux4}.

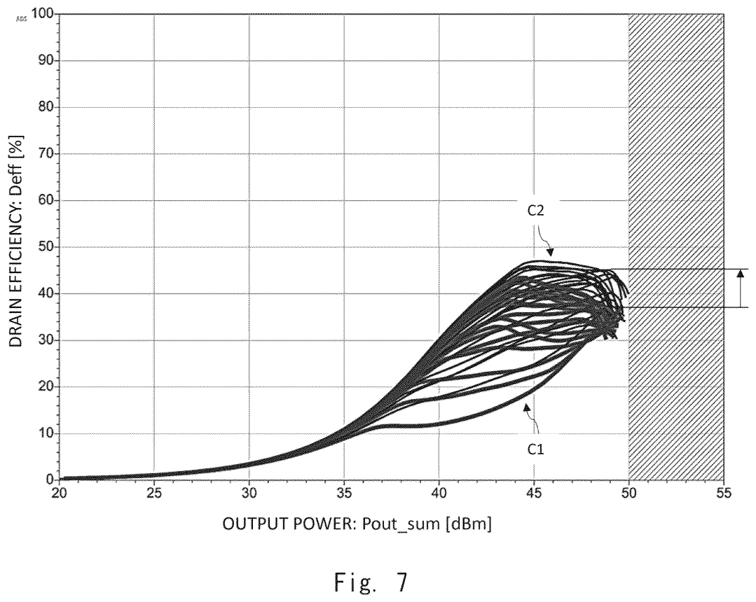

FIG. 7 illustrates simulation results of drain efficiency in an asymmetric distributed power amplifier 100 composed of a main amplifier 110 and four stages of auxiliary amplifiers. A thick curved line C1 illustrates a simulation result when a model of a 30 W class element (e.g., FET) is applied to the auxiliary amplifier 121 of the first stage and a model of a 10 W class element is applied to the other auxiliary amplifiers. A thin curved line C2 illustrates a simulation result when a model of a 30 W class element (e.g., FET) is applied to the auxiliary amplifier 124 of the final stage and a model of a 10 W class element is applied to the other amplifiers. The operating frequency has been changed from 3.3 GHz to 5.0 GHz in 0.1 GHz step. As described above, when the high-output amplifier (30 W class) is arranged in the final stage, the conversion ratio of the desired impedance is suppressed. In this case, high efficiency characteristics are acquired from the back-off peak after the start of the operation of the auxiliary amplifier to the entire saturation region.

### Other Example Embodiment

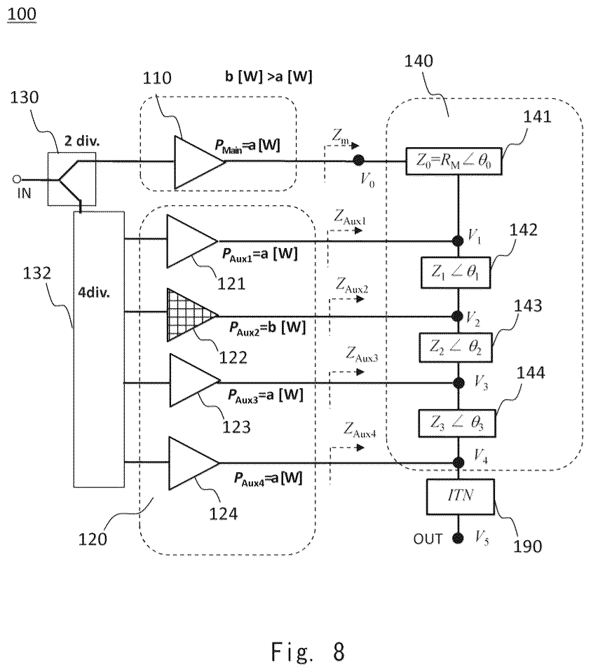

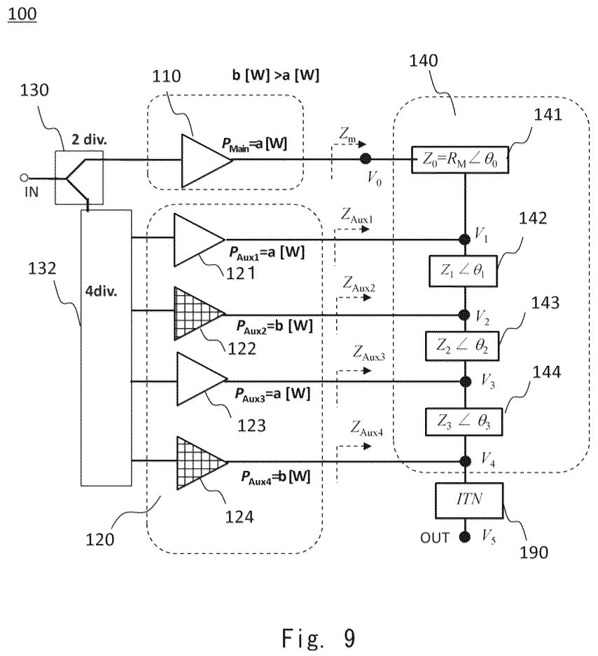

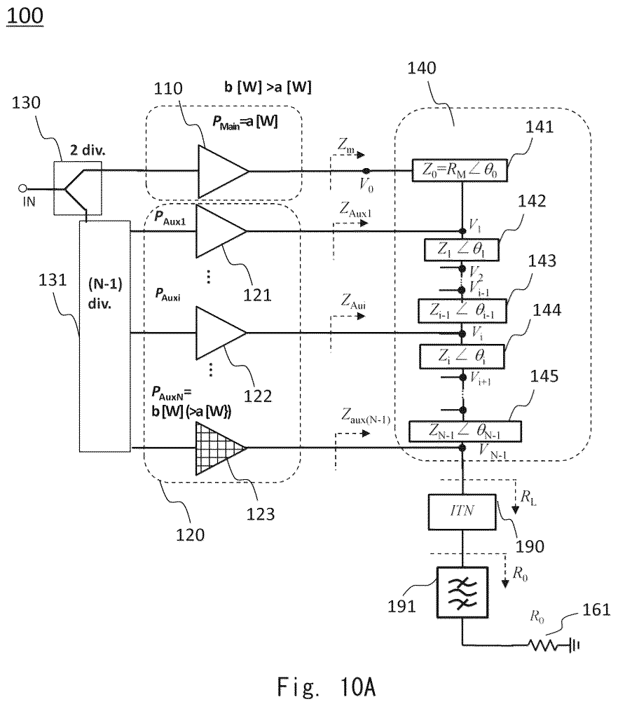

In FIGS. 1 and 2, the auxiliary amplifier having a large output power is arranged in the final stage, but as illustrated in FIG. 8, an auxiliary amplifier having a large maximum output power may be arranged in the second stage. Alternatively, as illustrated in FIG. 9, an auxiliary amplifier having a large maximum output power may be arranged at two positions of the second stage and the fourth stage. As described above, the auxiliary amplifier having a large maximum output power may be arranged in any stage of the second and subsequent stages, depending on the desired output power, device characteristics, and the like.

In short, in FIG. 1 and the like, the output end of the auxiliary amplifier having a maximum output voltage larger than the maximum output power of the main amplifier 110 is connected to the end portion on the output side of the N-th stage transmission line. However, the output end of the auxiliary amplifier having the maximum output voltage larger than the maximum output power of the main amplifier 110 may be connected to the end portion on the output side of any one of the transmission lines in the second and subsequent stages.

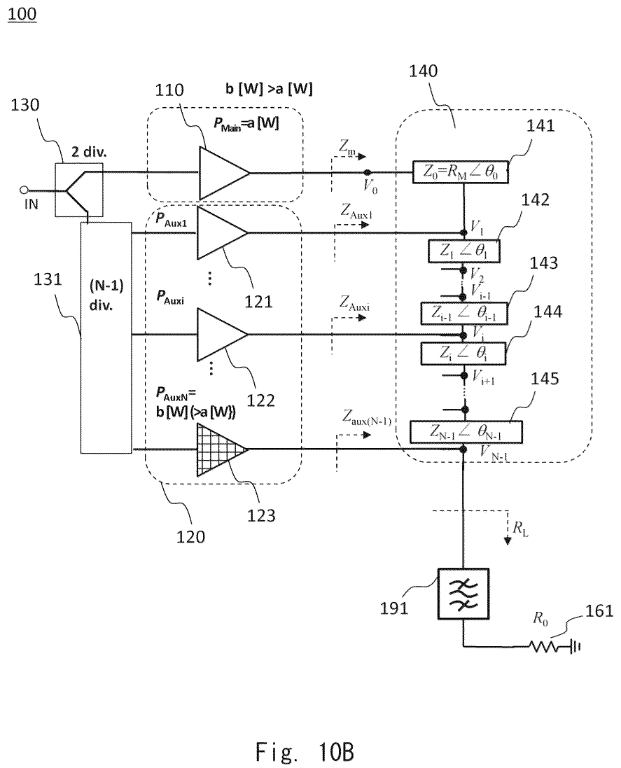

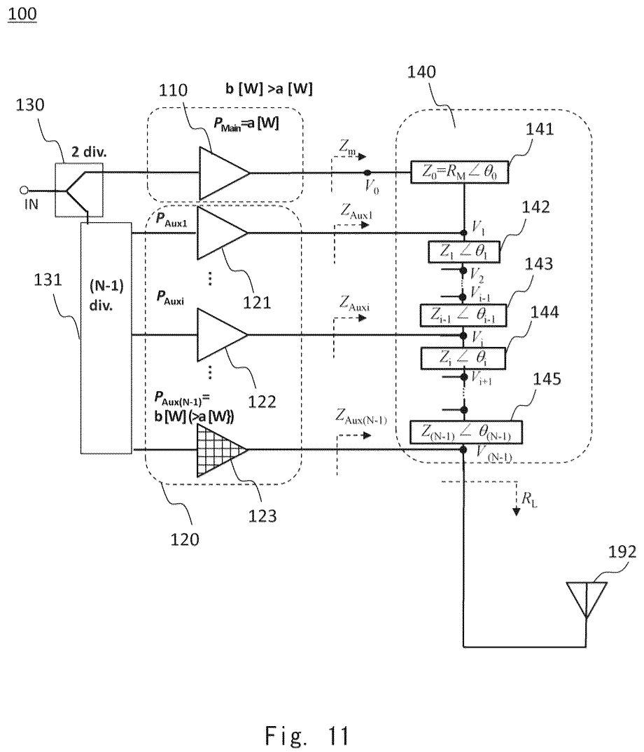

Further, as illustrated in FIG. 10A, a multi-stage impedance conversion circuit (ITN: Impedance Transforming Network(s)) 190 similar to the combining circuit 140 may be provided according to a connection with a subsequent-stage circuit. The impedance conversion circuit 190 converts an impedance R_{L} again to a reference impedance such as 50Ω, but leads to an increase in circuit size. On the other hand, in order to suppress unnecessary radiation, a filter circuit 191 may be provided at a stage subsequent to the distributed power amplifier 100. A load 161 is connected to an output side of the filter circuit 191. In this case, input/output matching of the filter circuit 191 can be performed on R_{L} without being performed on the reference impedance such as 50Ω. As illustrated in FIG. 10B, the filter circuit 191 having a filtering function and having an impedance conversion function is designed together with the distributed power amplifier 100, whereby the circuit size can be reduced. An input end of the filter circuit 191 is connected to an end portion on an output side of the (N-1)-th stage transmission line. An input impedance of the filter circuit 191 is conjugate matched to an output impedance R_{L}.

When the filter circuit 191 is unnecessary, an input impedance of an antenna 192 may be designed to be conjugate matched to the output impedance R_{L}, as illustrated in FIG. 11. This reduces the circuit size. Since the impedance conversion circuit 190 is unnecessary, transmission loss is reduced.

### Supplement to Theoretical Analysis

Loads are determined from specifications of an output back-off point (OBO) [dB], maximum capable output power Pₘₐₓ, a drain bias voltage V_{dd}, a knee voltage Vₖ, and the like, and the above-described Equations (1) and (2). The loads include R_{L} and R_{M}. R_{L} represents an output impedance of the distributed power amplifier. R_{M} represents an output impedance of the main amplifier. The impedance conversion circuit for converting R_{L} into R_{M} in a desired frequency band is a multi-stage impedance conversion combining circuit of (N-1) stages that is equivalent to the number of stages of the auxiliary amplifiers. A type of the impedance conversion circuit (e.g., Chebyshev type) is selected as appropriate, and a characteristic impedance Zᵢ (i=1 to N-1) of each stage is determined.

An output current Iₘ during the operation of the main amplifier (V_{IN}<Vₜₕ) is expressed by Equation (7). An output current Iₘ during the operation of the auxiliary amplifier group (V_{IN}≥Vₜₕ) is expressed by Equation (8).

$$\begin{matrix}[ Mathematical formula 7 ] & \\ {I}_{m} = {I}_{m\_max} \frac{{10}^{OBO / 20}}{{V}_{IN \_ max}} \cdot {V}_{IN} & ( 7 )\end{matrix}$$

$$\begin{matrix}[ Mathematical formula 8 ] & \\ {I}_{m} = {I}_{m\_max} = const . & ( 8 )\end{matrix}$$

After the output of the main amplifier is saturated, the auxiliary amplifier connected to each node point between the stages of the multi-stage combining circuit is operated, whereby a current I_{Ai} is applied thereto. At this time, a voltage amplitude at the time of saturation of all the node points converges to a constant value and R_{M}=const. is maintained during low-output operation without any current source for flowing I_{Ai}. Equation (9) is established from the above-described condition, i.e., a condition that load modulation is not performed. From Equation (9), a maximum current amount I_{Ai_max} is calculated.

$$[ Mathematical formula 9 ]$$

$${I}_{Ai\_max} = ( {V}_{dd} - {V}_{k} ) ( {Y}_{i} - {Y}_{( i - 1 )} ) \frac{{V}_{α}}{{V}_{dd}} = ( {V}_{dd} - {V}_{k} ) ( \frac{1}{{Z}_{1}} - \frac{1}{{Z}_{( i - 1 )}} ) \frac{π ( {V}_{dd} - {V}_{k} )}{2 ( π - 1 ) {V}_{dd}} = \frac{π}{2 ( π - 1 )} ( \frac{1}{{Z}_{1}} - \frac{1}{{Z}_{( i - 1 )}} ) \frac{{( {V}_{dd} - {V}_{k} )}^{2}}{{V}_{dd}} \qquad ( 9 )$$

A required current ratio of each auxiliary amplifier is expressed by Equation (10). A dependency of I_{Ai} on the input voltage V_{IN} is expressed by Equation (11).

$$\begin{matrix}[ Mathematical formula 10 ] & \\ {I}_{A \text{?} N} : {I}_{A \text{?} ( N - 1 )} : … : {I}_{{A}_{2}} : {I}_{{A}_{1}} = ( \frac{1}{{R}_{L}} - \frac{1}{{Z}_{( N - 1 )}} ) : ( \frac{1}{{Z}_{( N - 1 )}} - \frac{1}{{Z}_{( N - 2 )}} ) : … : ( \frac{1}{{Z}_{2}} - \frac{1}{{Z}_{1}} ) : 1 & ( 10 )\end{matrix}$$

$$\begin{matrix}[ Mathematical formula 11 ] & \\ {I}_{Ai} = {I}_{Ai \_ max} \frac{( {10}^{OBO / 20} \cdot {V}_{IN} - {V}_{IN \_ max} )}{( {10}^{OBO / 20} - 1 ) {V}_{IN \_ max}} & ( 11 )\end{matrix}$$

$$\text{?} \text{indicates text missing or illegible when filed}$$

A dependency of each node-point voltage Vᵢ on the input voltage V_{IN} is expressed by Equations (12) and (13). i in Equation (13) is an integer of 2 or more and N or less. After the auxiliary amplifier is operated (V_{IN}≥Vₜₕ), a successive Vᵢ is acquired from a recurrence equation for the node-point voltage before two nodes. [a] is a Gaussian symbol and represents the largest integer not exceeding a.

$$\begin{matrix}[ Mathematical formula 12 ] & \\ {V}_{0} = {V}_{1} = \{ \begin{matrix}{V}_{IN} \cdot ( {10}^{\frac{OBO}{20}} \cdot \frac{{R}_{M} {I}_{M \_ max}}{{V}_{IN \_ max}} ) ( Vin < Vth ) \\ {R}_{M} {I}_{M \_ max} ( Vin \geq Vth )\end{matrix} \} & ( 12 )\end{matrix}$$

$$\begin{matrix}[ Mathematical formula 13 ] & \\ {V}_{i} = \{ \begin{matrix}{V}_{IN} \cdot ( {10}^{\frac{OBO}{20}} \cdot \frac{{R}_{M} {I}_{M \_ max}}{{V}_{IN \_ max}} ) {\prod }_{{k = 1}_{( j - 2 k \geq 0 )}}^{[ \frac{i + 1}{2} ]} ( \frac{{Z}_{( i - ( 2 k - 1 )}}{{Z}_{( i - 2 k )}} ) ( Vin < Vth ) \\ \begin{matrix}{I}_{A ( i - 1 ) \text{?} max} {Z}_{( i - 1 )} \frac{{10}^{OBO / 20} \cdot {V}_{IN} - {V}_{IN \_ max}}{( {10}^{OBO / 20} - 1 ) {V}_{IN \_ max}} + \\ ( \frac{{Z}_{( i - 1 )}}{{Z}_{( i - 2 )}} ) \cdot {V}_{( i - 2 )} ( Vin \geq Vth )\end{matrix}\end{matrix} & ( 13 )\end{matrix}$$

$$\text{?} \text{indicates text missing or illegible when filed}$$

The total power of Vᵢ in the Vᵢₙ<Vₜₕ is expressed by Equation (14). When defined as in Equation (15), the total power of Vᵢ of six stages of auxiliary amplifiers is expressed by Equations (16) to (20).

$$\begin{matrix}[ Mathematical formula 14 ] & \\ {\prod }_{{k = 1}_{( j - 2 k \geq 0 )}}^{[ \frac{i + 1}{2} ]} ( \frac{{Z}_{( i - ( 2 k - 1 )}}{{Z}_{( i - 2 k )}} ) & ( 14 )\end{matrix}$$

$$\begin{matrix}[ Mathematical formula 15 ] & \\ {\prod }_{{k = 1}_{( j - 2 k \geq 0 )}}^{[ ( 1 + 1 ) / 2 ]} ( \frac{{Z}_{( i - ( 2 k - 1 )}}{{Z}_{( i - 2 k )}} ) = \frac{{Z}_{0}}{{Z}_{- 1}} := 1 & ( 15 )\end{matrix}$$

$$\begin{matrix}[ Mathematical formula 16 ] & \\ {\prod }_{{k = 1}_{( j - 2 k \geq 0 )}}^{[ ( 2 + 1 ) / 2 ]} ( \frac{{Z}_{( i - ( 2 k - 1 )}}{{Z}_{( i - 2 k )}} ) = \frac{{Z}_{( 2 - ( 2 - 1 ) )}}{{Z}_{( 2 - 2 )}} = \frac{{Z}_{1}}{{Z}_{0}} & ( 16 )\end{matrix}$$

$$\begin{matrix}[ Mathematical formula 17 ] & \\ {\prod }_{{k = 1}_{( j - 2 k \geq 0 )}}^{[ ( 3 + 1 ) / 2 ]} ( \frac{{Z}_{( i - ( 2 k - 1 )}}{{Z}_{( i - 2 k )}} ) = \frac{{Z}_{( 3 - ( 2 - 1 ) )}}{{Z}_{( 3 - 2 )}} = \frac{{Z}_{2}}{{Z}_{1}} & ( 17 )\end{matrix}$$

$$\begin{matrix}[ Mathematical formula 18 ] & \\ {\prod }_{{k = 1}_{( j - 2 k \geq 0 )}}^{[ ( 4 + 1 ) / 2 ]} ( \frac{{Z}_{( i - ( 2 k - 1 )}}{{Z}_{( i - 2 k )}} ) = \frac{{Z}_{( 4 - ( 2 - 1 )}}{{Z}_{( 4 - 2 )}} \frac{{Z}_{( 4 - ( 2 * 2 - 1 ) )}}{{Z}_{( 4 - ( 2 * 2 ) )}} = \frac{{Z}_{3}}{{Z}_{2}} \frac{{Z}_{1}}{{Z}_{0}} & ( 18 )\end{matrix}$$

$$\begin{matrix}[ Mathematical formula 19 ] & \\ {\prod }_{{k = 1}_{( j - 2 k \geq 0 )}}^{[ ( 5 + 1 ) / 2 ]} ( \frac{{Z}_{( i - ( 2 k - 1 )}}{{Z}_{( i - ( 2 k ) )}} ) = \frac{{Z}_{( 5 - ( 2 * 1 - 1 ) )}}{{Z}_{( 5 - ( 2 * 1 ) )}} \frac{{Z}_{( 5 - ( 2 * 2 - 1 ) )}}{{Z}_{( 5 - ( 2 * 2 ) )}} = \frac{{Z}_{4}}{{Z}_{3}} \frac{{Z}_{2}}{{Z}_{1}} & ( 19 )\end{matrix}$$

$$\begin{matrix}[ Mathematical formula 20 ] & \\ {\prod }_{{k = 1}_{( j - 2 k \geq 0 )}}^{[ ( 6 + 1 ) / 2 ]} ( \frac{{Z}_{( i - ( 2 k - 1 )}}{{Z}_{( i - ( 2 k ) )}} ) = \frac{{Z}_{( 6 - ( 2 * 1 - 1 ) )}}{{Z}_{( 6 - ( 2 * 1 ) )}} \frac{{Z}_{( 6 - ( 2 * 2 - 1 ) )}}{{Z}_{( 6 - ( 2 * 2 ) )}} \frac{{Z}_{( 6 - ( 2 * 3 - 1 ) )}}{{Z}_{( 6 - ( 2 * 3 ) )}} = \frac{{Z}_{5}}{{Z}_{4}} \frac{{Z}_{3}}{{Z}_{2}} \frac{{Z}_{1}}{{Z}_{0}} & ( 20 )\end{matrix}$$

Therefore, load modulation characteristics Zₘ and Z_{Ai} when there are six stages of auxiliary amplifiers are expressed from Equation (21) as in Equations (22) to (28). Similarly to FIG. 5 when there are four stages of auxiliary amplifiers, Z_{Ai} decreases as the auxiliary amplifier goes to the subsequent stage.

$$\begin{matrix}[ Mathematical formula 21 ] & \\ {Z}_{Ai} = \frac{{V}_{i}}{{I}_{Ai}} & ( 21 )\end{matrix}$$

$$\begin{matrix}[ Mathematical formula 22 ] & \\ {Z}_{m} = {Z}_{0} = {R}_{M} & ( 22 )\end{matrix}$$

$$\begin{matrix}[ Mathematical formula 23 ] & \\ {Z}_{A 1} = \frac{{I}_{M\_max}}{{I}_{A 1 \_max}} {Z}_{0} \cdot \frac{( {10}^{\frac{OBO}{20}} - 1 ) {V}_{IN \_ max}}{( {10}^{\frac{OBO}{20}} \cdot {V}_{IN} - {V}_{IN \_ max} )} & ( 23 )\end{matrix}$$

$$\begin{matrix}[ Mathematical formula 24 ] & \\ {Z}_{A 2} = \frac{{I}_{A 1 \_max}}{{I}_{A 2 \_max}} {Z}_{1} + \frac{{I}_{M\_max}}{{I}_{A 2 \_max}} {Z}_{1} \cdot \frac{( {10}^{\frac{OBO}{20}} - 1 ) {V}_{IN \_ max}}{( {10}^{\frac{OBO}{20}} \cdot {V}_{IN} - {V}_{IN \_ max} )} & ( 24 )\end{matrix}$$

$$\begin{matrix}[ Mathematical formula 25 ] & \\ {Z}_{A 3} = \frac{{I}_{A 2 \_max}}{{I}_{A 3 \_max}} {Z}_{2} + \frac{{R}_{M} {I}_{M\_max}}{{Z}_{1} {I}_{A 3 \_max}} {Z}_{2} \cdot \frac{( {10}^{\frac{OBO}{20}} - 1 ) {V}_{IN \_ max}}{( {10}^{\frac{OBO}{20}} \cdot {V}_{IN} - {V}_{IN \_ max} )} & ( 25 )\end{matrix}$$

$$\begin{matrix}[ Mathematical formula 26 ] & \\ {Z}_{A 4} = \frac{{I}_{A 3 \_max}}{{I}_{A 4 \_max}} {Z}_{3} + \frac{{Z}_{1} {I}_{A 1 \_max}}{{Z}_{2} {I}_{A 4 \_max}} {Z}_{3} + \frac{{Z}_{1} {I}_{M\_max}}{{Z}_{2} {I}_{A 4 \_max}} {Z}_{3} \cdot \frac{( {10}^{\frac{OBO}{20}} - 1 ) {V}_{IN \_ max}}{( {10}^{\frac{OBO}{20}} \cdot {V}_{IN} - {V}_{IN \_ max} )} & ( 26 )\end{matrix}$$

$$\begin{matrix}[ Mathematical formula 27 ] & \\ {Z}_{A 5} = \frac{{I}_{A 4 \_max}}{{I}_{A 5 \_max}} {Z}_{4} + \frac{{Z}_{2} {I}_{A 2 \_max}}{{Z}_{3} {I}_{A 5 \_max}} {Z}_{4} + \frac{{Z}_{2} {R}_{M} {I}_{M\_max}}{{Z}_{3} {Z}_{1} {I}_{A 5 \_max}} {Z}_{4} \cdot \frac{( {10}^{\frac{OBO}{20}} - 1 ) {V}_{IN \_ max}}{( {10}^{\frac{OBO}{20}} \cdot {V}_{IN} - {V}_{IN \_ max} )} & ( 27 )\end{matrix}$$

$$\begin{matrix}[ Mathematical formula 28 ] & \\ {Z}_{A 6} = \frac{{I}_{A 5 \_max}}{{I}_{A 6 \_max}} {Z}_{5} + \frac{{Z}_{3} {I}_{A 3 \_max}}{{Z}_{4} {I}_{A 6 \_max}} {Z}_{5} + \frac{{Z}_{3} {Z}_{1} {I}_{A 1 \_max}}{{Z}_{2} {Z}_{4} {I}_{A 6 \_max}} {Z}_{5} + \frac{{Z}_{3} {Z}_{1} {I}_{M\_max}}{{Z}_{4} {Z}_{2} {I}_{A 6 \_max}} {Z}_{5} \cdot \frac{( {10}^{\frac{OBO}{20}} - 1 ) {V}_{IN \_ max}}{( {10}^{\frac{OBO}{20}} \cdot {V}_{IN} - {V}_{IN \_ max} )} & ( 28 )\end{matrix}$$

The present disclosure is not limited to the above-described example embodiments, and can be appropriately modified without departing from the spirit.

The present disclosure can provide a distributed power amplifier that operates with high efficiency in a wide frequency band.

While the disclosure has been particularly shown and described with reference to embodiments thereof, the disclosure is not limited to these embodiments. It will be understood by those of ordinary skill in the art that various changes in form and details may be made therein without departing from the spirit and scope of the present disclosure as defined by the claims.

What is claimed is:

1. A distributed power amplifier comprising:
a two-divider configured to divide an input signal to two signals;
a main amplifier configured to amplify one of the two signals;
(N-1) dividers configured to divide another of the two signals into (N-1) signals (N is a natural number of 3 or more);
(N-1) auxiliary amplifiers configured to amplify the (N-1) signals, respectively; and
(N-1) stages of transmission lines having different characteristic impedances from one another and being connected in series with one another, wherein
an output end of the main amplifier is connected to an end portion on an input side of a transmission line in a first stage of the (N-1) stages of transmission lines,
output ends of the (N-1) auxiliary amplifiers are connected to end portions on an output side of the (N-1) stages of transmission lines, respectively,
only the main amplifier performs amplification operation when a power level of the input signal is small, and the (N-1) auxiliary amplifiers start operations at once after a power level of an output signal of the main amplifier reaches a predetermined power level, and
the (N-1) auxiliary amplifiers include an auxiliary amplifier having maximum output power larger than maximum output power of the main amplifier.

2. The distributed power amplifier according to claim 1, wherein the output end of the auxiliary amplifier having maximum output power larger than maximum output power of the main amplifier is connected to an end portion on the output side of any one of transmission lines in a second and subsequent stages.

3. The distributed power amplifier according to claim 1, wherein the output end of the auxiliary amplifier having maximum output power larger than maximum output power of the main amplifier is connected to an end portion on the output side of a (N-1)-th stage transmission line.

4. The distributed power amplifier according to claim 1, wherein
a bias voltage of the main amplifier is set in such a way that the main amplifier operates in Class A or Class AB, and
a bias voltage of the (N-1) auxiliary amplifiers is set in such a way that the (N-1) auxiliary amplifiers operate in Class C.

5. The distributed power amplifier according to claim 1, wherein each of the (N-1) stages of transmission lines has an electrical length of approximately 90 degrees.

6. The distributed power amplifier according to claim 1, wherein a characteristic impedance of the (N-1) stages of transmission lines is set in such a way that a combining circuit including the (N-1) stages of transmission lines forms a Chebyshev type broadband impedance conversion circuit.

7. The distributed power amplifier according to claim 1, further comprising a filter circuit having an impedance conversion function, wherein
an input end of the filter circuit is connected to an end portion on the output side of a (N-1)-th stage transmission line, and
an input impedance of the filter circuit is conjugate-matched with an output impedance at an end portion on the output side of the (N-1)-th stage transmission line.

8. The distributed power amplifier according to claim 1, further comprising an antenna connected to an end portion on the output side of a (N-1)-th stage transmission line,
wherein an input impedance of the antenna is conjugate-matched with an output impedance at an end portion on the output side of the (N-1)-th stage transmission line.
